(19) United States
(12) Patent Application Publication
(10) Pub. No.: US 2017/0179979 A1
(43) Pub. Date: Jun. 22, 2017

(54) Systems and Methods for Minimum Storage Regeneration Erasure Code Construction Using r-Ary Trees

(71) Applicant: NetApp, Inc., Sunnyvale, CA (US)

(72) Inventor: Syed Abid Hussain, Bangalore (IN)

(21) Appl. No.: 14/974,799

(22) Filed: Dec. 18, 2015

(51) Int. Cl. H03M 13/15; H03M 13/00; G06F 11/10

(52) U.S. Cl. CPC H03M 13/154; G06F 11/1076; H03M 13/615

(57) ABSTRACT

m r-Ary trees for generating High-Rate MSR (HMSR) erasure codes for application in data storage systems. Nodes in the tree structures represent systematic and parity storage nodes. Each parity symbol for the HMSR erasure codes will be a linear combination of maximum k+k/r systematic symbols. The tree structures show that when a systematic node fails, its original systematic symbols can be recovered by accessing β symbols for each of its leaf nodes from each of the remaining nodes. Traversing the m r-Ary trees to design a codeword array will provide the linear equations needed to solve for and recover the lost systematic symbols. When forming the linear equations, random number or other coefficients can be added to the systematic symbols to construct the parity symbols. The parities of the HMSR erasure code will ensure recovery of any systematic node failure using significantly reduced IO and network bandwidth.

### TECHNICAL FIELD

The present disclosure relates generally to storage systems and more specifically to a methodology to generate Help-By-Transfer (HBT) Minimum Storage Regenerating (MSR) erasure codes for high-rate erasure in a storage device.

### BACKGROUND

In a large-scale distributed storage system, individual storage nodes will commonly fail or become unavailable from time to time. Therefore, storage systems typically implement some type of recovery scheme for recovering data that has been lost, degraded or otherwise compromised due to node failure or otherwise. One such scheme is known as erasure coding. Erasure coding generally involves the creation of codes used to introduce data redundancies (also called “parity data”) that is stored along with original data (also referred to as “systematic data”), to thereby encode the data in a prescribed manner. If any systematic data or parity data becomes compromised, such data can be recovered through a series of mathematical calculations.

At a basic level, erasure coding for a storage system involves splitting a data file of size M into X chunks, each of the same size M/X. An erasure code is then applied to each of the X chunks to form A encoded data chunks, which again each have the size M/X. The effective size of the data is A*M/X, which means the original data file M has been expanded A/X times, with the condition that A≧X. Now, any X chunks of the available A encoded data chunks can be used to recreate the original data file M. The erasure code applied to the data is denoted as (n, k), where n represents the total number of nodes across which all encoded data chunks will be stored and k represents the number of systematic nodes (i.e., nodes that store only systematic data) employed. The number of parity nodes (i.e., nodes that store parity data) is thus n−k=r. Erasure codes following this construction are referred to as maximum distance separable (MDS) if for any loss of a maximum r nodes, such nodes are recoverable using data stored on exactly k nodes

A simple example of a (4, 2) erasure code applied to a data file M is shown in FIG. 1. As shown, a data file M is split into two chunks X₁, X₂ of equal size and then an encoding scheme is applied to those chunks to produce 4 encoded chunks A₁, A₂, A₃, A₄. By way of example, the encoding scheme may be one that results in the following relationships: A₁=X₁; A₂=X₂; A₃=X₁+X₂; and A₄=X₁+2*X₂. In this manner, the 4 encoded data chunks can be stored across a storage network 102, such that the one encoded data chunk is stored in each of four storage nodes 104a-d. Then, the encoded data chunks stored in any 2 of the four storage nodes 104a-d can be used to recover the entire original data file M. This means that the original data file M can be recovered if any two of the storage nodes 102a-d fail, which would not be possible with traditional “mirrored” back-up data storage schemes.

Disk failure (or unavailability) occurs frequently in large-scale distributed storage systems. While some commonly employed MDS codes, like the Reed Solomon code, are very good in terms of requiring reduced storage overhead, they can impose a significant burden on the storage system I/O when recovering a failed or unavailable disk. In other words, a significant amount of disk I/O must be dedicated to recover the failed or unavailable disk, which consumes system resources and impacts performance. Minimum-storage regenerating (MSR) code is a class of MDS codes that in theory promises to provide significant reduction in disk I/O during repair. These codes, at the same time, do not compromise either in storage overhead or in reliability when compared to the Reed-Solomon code.

In an MSR coding scheme, every storage node of a storage network contains a set of data, represented in coding theory as “symbols.” This is referred to as “sub-packetization.” MSR codes require minimum storage space per storage node. To recover a particular failed storage node, only a sub-set of all symbols stored on each surviving storage node must be accessed (e.g., transferred to the new or repaired node) to regenerate the data set that was lost. This number of symbols is known to be close to the information theoretical minimum. In other words, if each storage node stores a symbols, only a subset β of the symbols will need to be obtained from each of d surviving storage nodes to recover a failed storage node.

The amount of data needed to be transferred to the new or repaired node to regenerate the data set lost when a node failed or became unavailable is known as the “repair bandwidth.” The repair bandwidth dβ is thus a function of the amount of data β accessed at each surviving node (referred to as “helper” nodes) and the number of helper nodes d that must be contacted. A so-called “help-by-transfer” regeneration code is one that does not require computation at the helper node before the data is transmitted. It follows that a help-by-transfer code possessing minimum sub-packetization is access optimal (AO), meaning that during a recovery process each surviving storage node needs to transmit only the symbols β that it accesses. See, I. Tamo, Z. Wang, and J. Bruck, “Access vs. Bandwidth in Codes for Storage,” IEEE International Symposium on Information Theory (ISIT 2012), July 2012, pp. 1187-1191, which is incorporated herein by reference.

The “code rate” for an (n, k) erasure code is defined as k/n or k/(k+r), which represents the proportion of the systematic data in the total amount of stored data (i.e., systematic data plus parity data). An erasure code having a code rate k/n>0.5 is deemed to be a high-rate erasure code. This means that the coding scheme will require a relatively large amount of systematic nodes k as compared to parity nodes r. Conversely, a low-rate (k/n≦0.5) erasure code will require a relatively small amount of systematic nodes k as compared to parity nodes r. High-rate erasure codes can thus be desirable because they require less storage overhead than low-rate erasure codes for a given set of systematic data.

It has been shown that the lower bound of sub-packetization for AO high-rate erasure codes is equal to r^{(k/r)}. See, I. Tamo, Z. Wang, and J. Bruck, “Access vs. Bandwidth in Codes for Storage,” IEEE International Symposium on Information Theory (ISIT 2012), July 2012, pp. 1187-1191, which is incorporated herein by reference. Attempts have recently been made to develop MSR erasure codes that account for this minimum sub-packetization bound r^{(k/r)}. See, K. A. Gaurav, B. Sashidharan and P. Vijaykumar, “An Alternate Construction of an Access-Optimal Regenerating Code with Optimal Sub-Packetization Level,” arXiv:1501.04760v1, 20 Jan. 2015, which is incorporated herein by reference. In that particular work, the authors demonstrated construction of MSR codes following an iterative approach. As exemplified by that work, known methods for constructing MSR codes rely on abstract mathematical approaches. While some prior works have proven the existence of high-rate MSR codes, there has yet to be demonstrated any practical approach for constructing a high-rate MSR code that can be applied practically to distributed storage system.

What is needed, therefore, is a relatively simple way to construct help-by transfer high-rate MSR erasure codes that use the minimum sub-packetization bound r^{(k/r)} and have practical application to distributed storage systems.

### BRIEF DESCRIPTION OF THE DRAWINGS

FIG. 1 is a block diagram illustrating a simple example of a (4, 2) erasure code applied to a data file M.

FIG. 2. is an illustration of an exemplary symbol array and an exemplary codeword array for a (6,4) MSR erasure code, according to certain exemplary embodiments.

FIG. 3 is a flowchart depicting an example of a method for generating m r-Ary tree structures and populating a symbol array and codeword array for a high-rate MSR erasure code, according to certain exemplary embodiments.

FIG. 4 is an illustration of exemplary m r-Ary tree structures for a (9, 6) MSR erasure code, generated according to the method described in FIG. 3.

FIG. 5 is a flowchart depicting an example of method for determining certain parity symbols for a (9, 6) MSR erasure code generated according to the method described in FIG. 3.

FIGS. 6A and 6B are illustrations of the exemplary m r-Ary tree structures shown in FIG. 4, annotated to further explain the method according to FIG. 5 for determining certain parity symbols.

FIG. 7 is an illustration of an exemplary symbol array and an exemplary codeword array for a (9, 6) high-rate MSR erasure code, generated according to the method described in FIG. 3.

FIG. 8 is a block diagram illustrating an example of a computing environment in which various embodiments may be implemented.

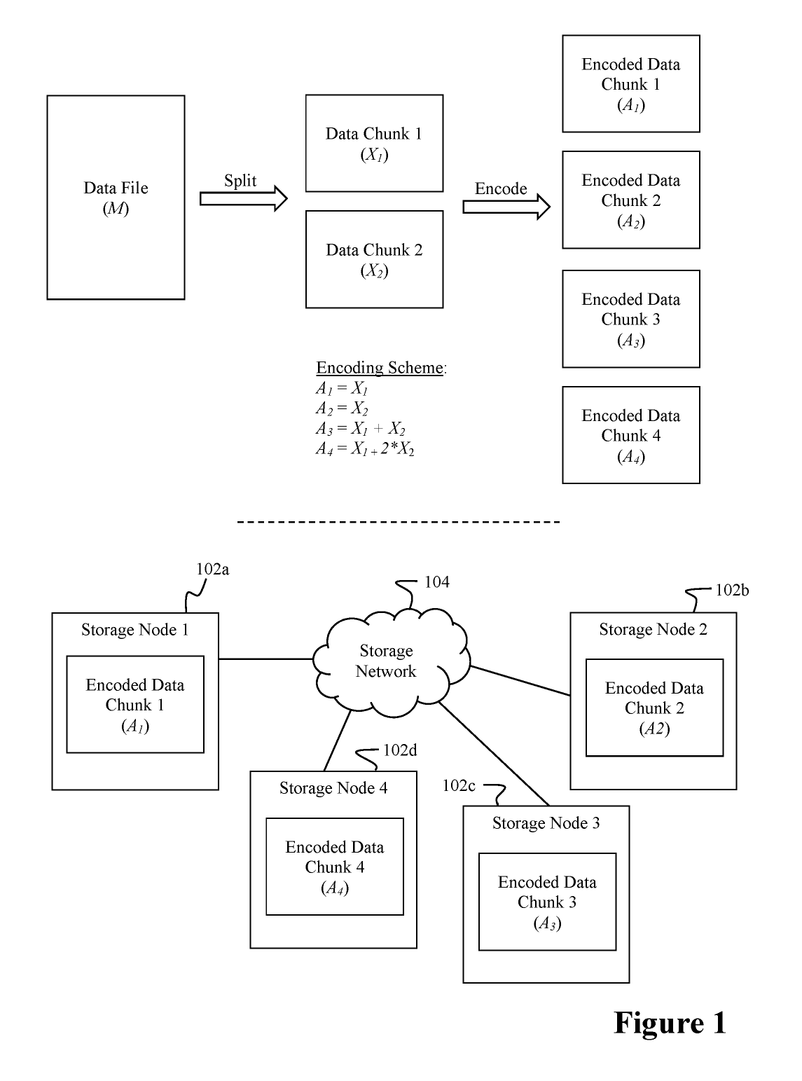

### DETAILED DESCRIPTION

The various embodiments described herein provide a conceptually simple approach for generating high-rate MSR erasure codes that have practical application in data storage systems. Embodiments include methods, systems and corresponding computer-executable instructions for generating tree structures and assigning indices to the nodes thereof, according to certain rules. The nodes in the tree structures will represent systematic storage nodes that store original systematic data and parity storage nodes that store redundant parity data. Systematic symbols for a high-rate MSR erasure code can be easily added to construct parity symbols of the codeword array representing the desired high-rate MSR erasure code, as will be appreciated. Each parity symbol will be linear combination of systematic symbols. When a systematic node fails, parity symbols from β rows from each of the parity nodes will provide the linear equations needed to solve for and recover the lost systematic symbols. By traversing the tree structures described herein in certain ways to be described, parity symbols for the codeword array can be determined. When forming linear combinations of the parity symbols for the codewords, random number coefficients or other coefficients (generated by some other technique, e.g., maintaining interference alignment) can be used for certain of the parity symbols, which will ensure a high-rate MSR erasure code that will have practical application in storage systems.

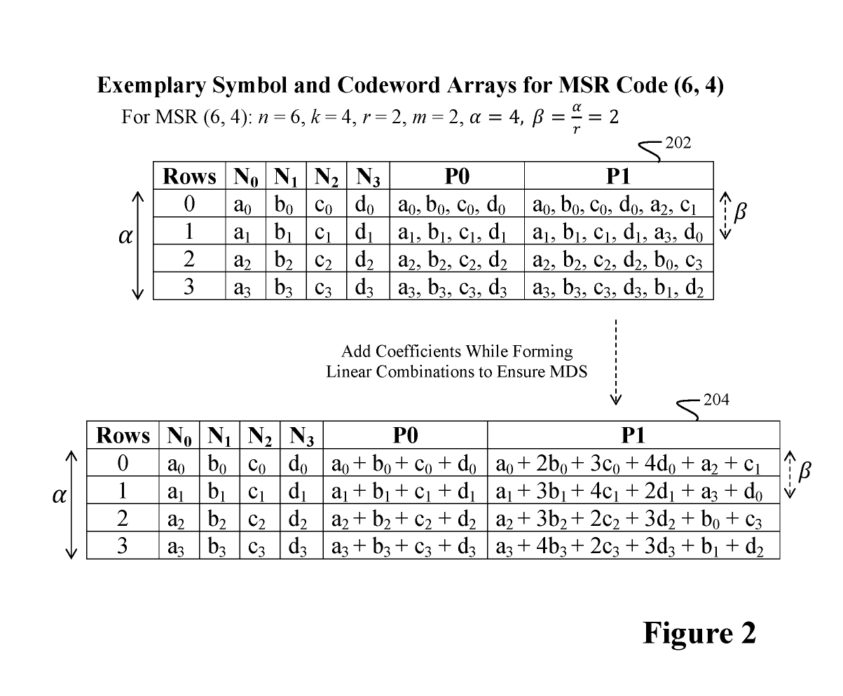

MSR codes may be expressed as “codeword arrays,” which are tables showing the systematic and parity symbols to be stored in each of the systematic and parity nodes used. FIG. 2 shows an exemplary codeword array 204 for a (6,4) MSR code and an array 202 of the symbols used to construct the codewords in the codeword array 204. In the illustrated example, a dataset of 16 symbols is distributed across 6 storage nodes (n), comprising 4 systematic nodes (k) and 2 parity nodes (r). The sub-packetization level (α) is 4. In the figure, N₀, N₁, N₂ and N₃ represent the 4 systematic nodes and P₀ and P₁ represent the 2 parity nodes. The symbol array 202 shows that in the construction of this exemplary MSR code, the first parity node (P₀) uses row parity, meaning that the parity symbol in each row of P₀ comprises a combination of the systematic symbols in the corresponding row of each of the systematic nodes (N₀−N₃). The parity symbols of the remaining parity node (P₁) are designed to meet the conditions that: (i) all data can be reconstructed by accessing any 4 of the nodes; and (ii) a failed systematic node can be recovered by accessing β=2 symbols from each of the 5 remaining helper nodes.

The symbol array 202 in FIG. 2 includes all systematic and parity symbols required to ensure repair of the systematic nodes. The codeword array 204 shows that each of the parity nodes P₀ and P₁ are linear combinations of the symbols in each of the respective rows for each of the respective parity nodes, with appropriate coefficients added to the parity symbols of the P₁ parity node in order to guarantee the vector MDS property of the code. The existence of such coefficients is proved in the previously-cited paper by Gaurav, Sashidharan and Vijaykumar. As will be appreciated, the construction of a symbol array 202 prior to construction of the codeword array 204 is an optional intermediate step.

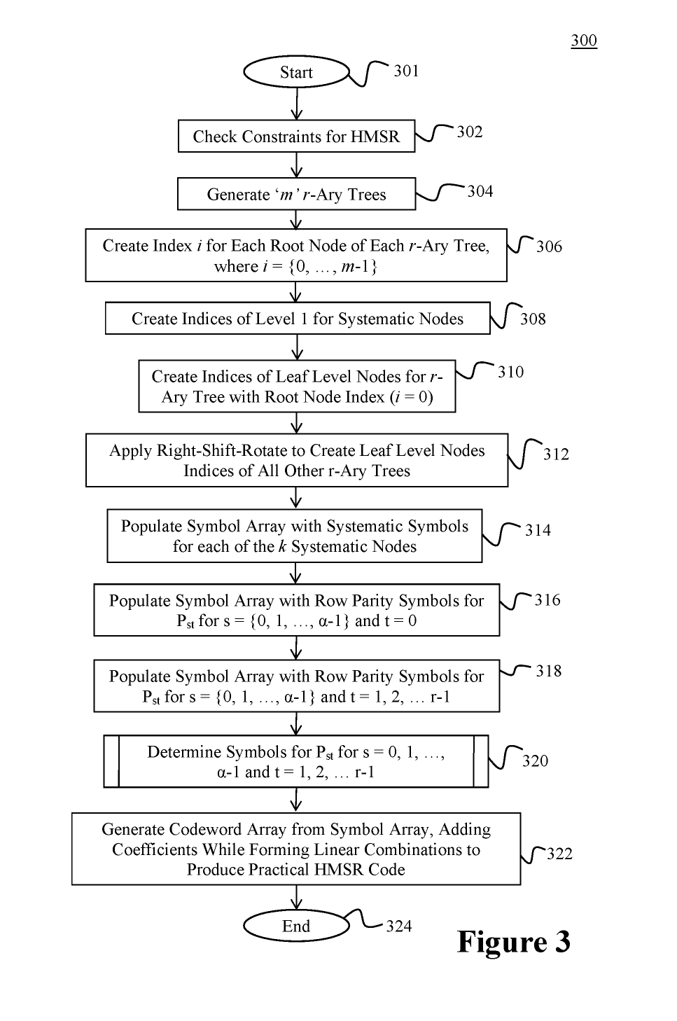

The following example discussed in reference to FIGS. 3 through 7 is intended to explain the construction of a codeword array for a high rate MSR code using r-Ary trees, according to certain embodiments. The example methodology relies on the precondition that the number of systematic nodes k is an integer multiple m greater than or equal to 2 of the number of parity nodes r. In other words, the following mathematical relationship holds: k=mr and m≧2. The methodology also uses the lower bound of sub-packetization of α=r^{m} for Access Optimal high rate erasure codes and β=α/r. Thus, in the case of a high-rate (9, 6) MSR code:

n=9

k=6

r=n−k=3

m=2

α=r^{m}=9

β=α/r=3

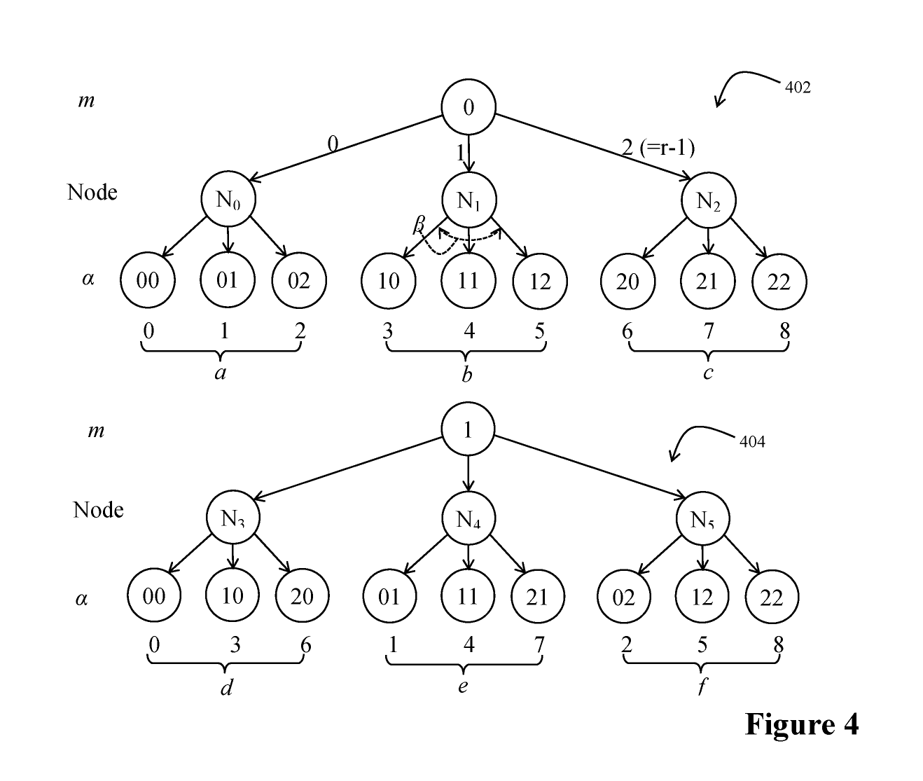

FIG. 3 is a flow chart illustrating an exemplary method 300 for constructing m r-Ary trees to represent the high-rate (9, 6) MSR erasure code according to certain embodiments, and FIG. 4 shows the resulting m r-Ary trees. As will be shown and explained, the m r-Ary trees are constructed such that if any systematic node (1^{st} level node) is lost, its systematic symbols can be recovered by accessing the parity symbols from the β rows given by its leaf-level tree-nodes. This design ensures that the erasure code generated based on the m r-Ary trees will be an MSR erasure code. The exemplary method 300 begins at start step 301 and then moves to step 302, where the constraints for the MSR erasure code are checked to confirm the above-noted preconditions (i.e., k=mr, m≧2, α=r^{m}, and β=α/r). Next, at step 304, the m r-Ary trees are generated. Given that m=2 and r=3 in this example, two trees are generated and each of the trees is a ternary tree, i.e., a tree with three levels in which each node has three children. See trees 402, 402 in FIG. 4.

Next at step 306, indices are created for the root node of each tree. Each of the m r-Ary trees is given the root node index i, where i={0, . . . , m−1}. Thus, as shown in FIG. 4, the root nodes of the two trees 402, 404 have indices 0 and 1. As also shown, each root node has r children, which can be referred to as first level nodes. Each first level node of each tree 402, 404 represents a systematic node in the storage system. At step 308, each first level (or systematic) node is given an index Nⱼ, where j=r*i+t, 0≦t≦r−1. Thus, as depicted in FIG. 4, in the current example each root node has r=3 first level children, for a total of six first level nodes across the two trees with indices {N₀, N₁, . . . , N₅}.

FIG. 4 also shows that each first level node has β leaf nodes (i.e., second level children) and each leaf node is indexed with a base-r m-digit number. These indices are created in steps 310 and 312 of method 300. First, at step 310, indices are created for each leaf node in the r-Ary tree with root node index i=0. For this tree, the base-r m-digit number is determined as follows: a₀, a₁ . . . aₘ₋₁, where 0≦aₛ≦r−1, s=0 to (r−1). Thus, as shown in FIG. 4, each first level child of the tree with root node index i=0 has β=3 leaf nodes, each of which is indexed with a sequential base-3 (i.e., ternary) 2-digit number. Indexing the a leaf nodes for the i=0 tree in this manner ensures that the sub-packetization index a will be limited by r^{(k/r)}−1 or r^{m}−1. The corresponding decimal form of each leaf node index is also noted, along with a sequential letter {a, b, c, . . . } designating each subtree of each 1^{st} level (i.e., systematic) node.

Next, at step 312, the indices for each r-Ary tree with root node index i≧1 are created. For these trees, each base-r m-digit number leaf node index is obtained by applying a right-shift-rotation operation i times to the corresponding leaf node index of the i=0 tree. FIG. 4 shows the resulting base-r m-digit number leaf node indices of the tree with root node index i=1, determined by applying a right-shift-rotation operation i=1 time to the corresponding leaf node index of the i=0 tree. The corresponding decimal form of each of the base-r m-digit number leaf node indices is also shown, as well as the letters designating each sub-tree.

After the m r-Ary trees are constructed and all node indices are assigned, the trees are complete. Then, based on the completed trees, a codeword array for the high rate MSR code can easily be obtained. As described above, such a codeword array can be represented as an array with a rows and n columns. The columns represent the systematic nodes and the parity nodes {N₀, N₁, . . . , Nₖ₋₁, P₀, P₁, . . . , Pᵣ₋₁}. The rows represent the symbols to be stored in the each of the systematic nodes and the parity nodes.

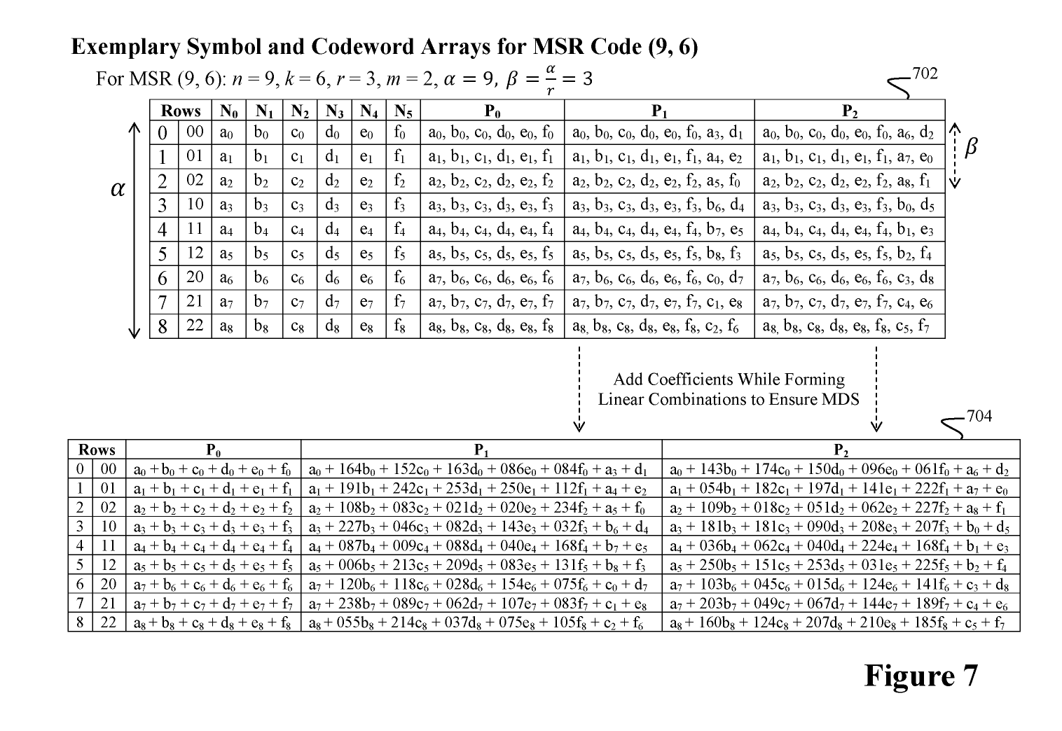

The example discussed herein with reference to FIGS. 3 through 7 includes the optional step of constructing a symbol array, from which a codeword array is then formed. The properties of the parity symbols in a symbol array constructed from the m r-Ary trees for the high-rate MSR code (n, k) can be described as follows. The symbol array will have a rows, each row is presented as base-r and m-digit number representing s={0, 1, . . . , α−1}. Each s^{th} row presents the n symbols denoted by the tuple Rₛ={aₛ, bₛ, cₛ, . . . , pₛ₀, pₛ₁, . . . , pₛ₍ᵣ₋₁₎}. The first k symbols in the tuple Rₛ represent symbols from the systematic nodes {N₀, N₁, . . . , Nₖ₋₁}. FIG. 7 shows an exemplary symbol array 702 and the corresponding exemplary codeword array 704. Accordingly, at step 314 of FIG. 3, the systematic node columns of the symbol array 702 are populated with the systematic symbols according to the above-noted property. As shown, the first k symbols in the tuple Rₛ for the example of a high-rate MSR (9, 6) erasure code are aₛ, bₛ, cₛ, dₛ, eₛ, fₛ.

The last r symbols in the tuple R, represent the symbols for the parity nodes {P₀, P₁, . . . , Pᵣ₋₁}. In accordance with certain embodiments, the parity symbols for a high-rate MSR erasure code (also referred to as a “HMSR erasure code”) must be designed so as to enable successful recovery from failure of one systematic node {N₀, N₁, . . . , Nₖ₋₁}. Also, the desired HMSR erasure code will be resilient to failure of any one systematic node for which the data to be downloaded for recovery is (n−1)β, which is what fulfills the MSR requirement.

To begin determination of parity symbols, the method 300 of FIG. 3 next moves to step 316, where the symbols for the first parity node P₀ are determined and added to the parity symbol array 702. The parity symbol pₛ₀ (s=0, . . . , α−1, i.e., the parity symbol in the s^{th} row for the parity node P₀) are an addition of the k systematic symbols {aₛ, bₛ, cₛ, . . . } from the same s^{th} row. Again, this is referred to as “row parity.”

The parity symbols for the remaining parity nodes pₛₜ (for t={1, 2, . . . , r−1}) are a combination of the k systematic symbols {aₛ, bₛ, cₛ, . . . } from the s^{th} row and an additional m systematic symbols from rows other than the same s^{th} row. As illustrated in FIG. 7 for the case of a HMSR (9, 6) erasure code, the parity symbols pₛ₁, pₛ₂ for the parity nodes P₁ and P₂ are each generated from the k=6 systematic symbols from the s^{th} row plus m=2 additional systematic symbols from different rows. Thus, at step 318 of FIG. 3, the k row parity symbols are added to the symbol array for each Pₛₜ for s={0, 1, . . . , α−1} and t=1, 2, . . . r−1.

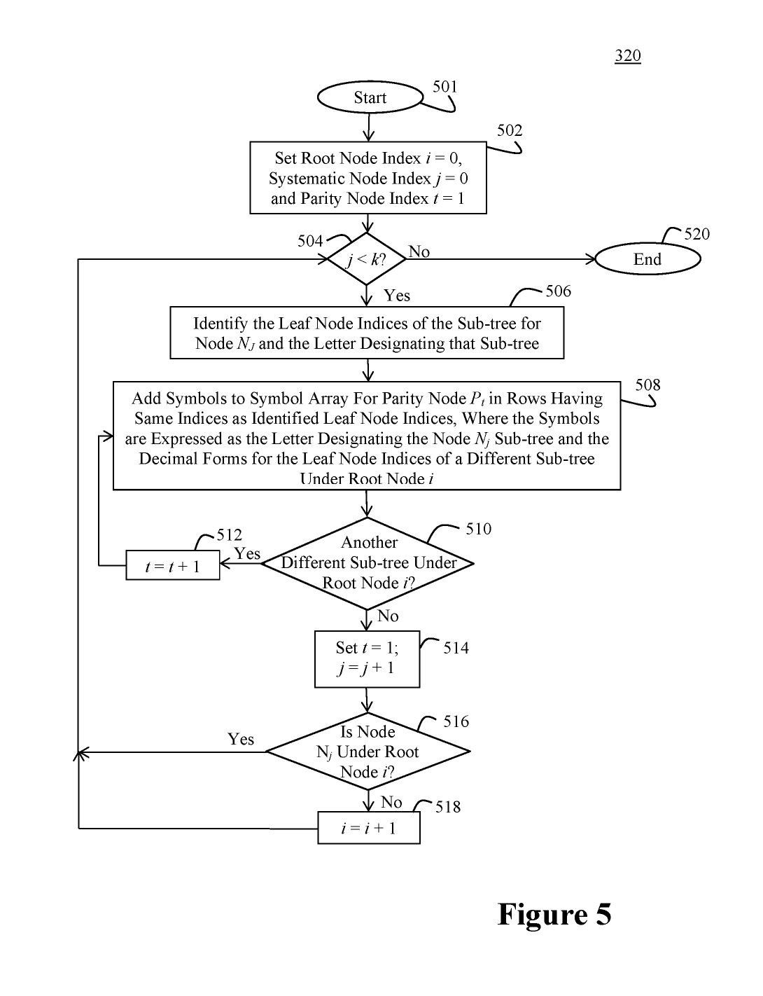

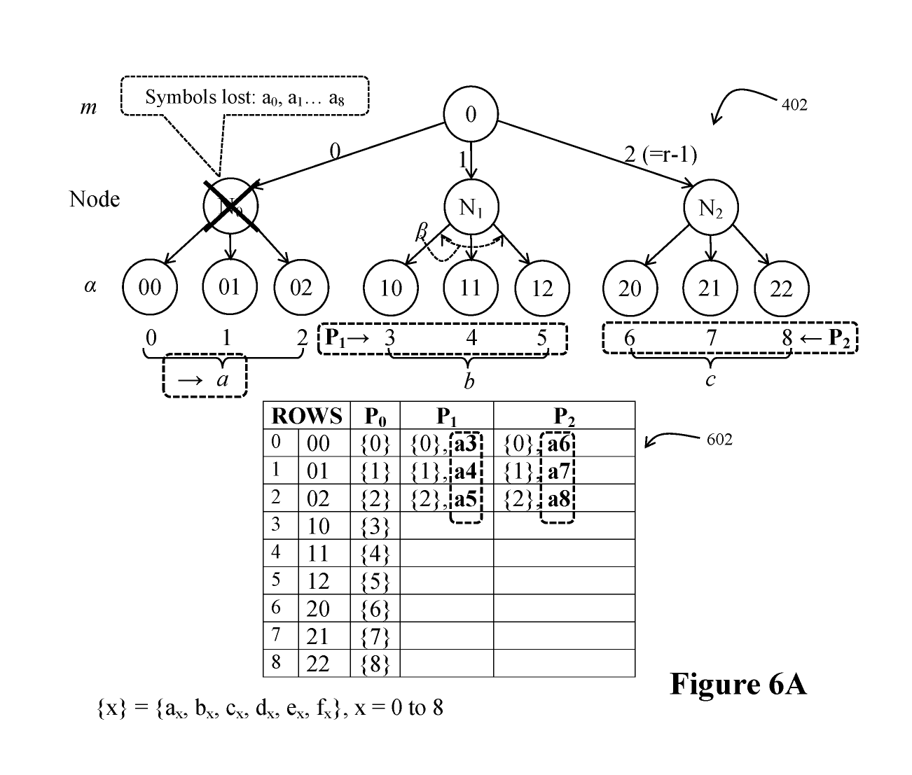

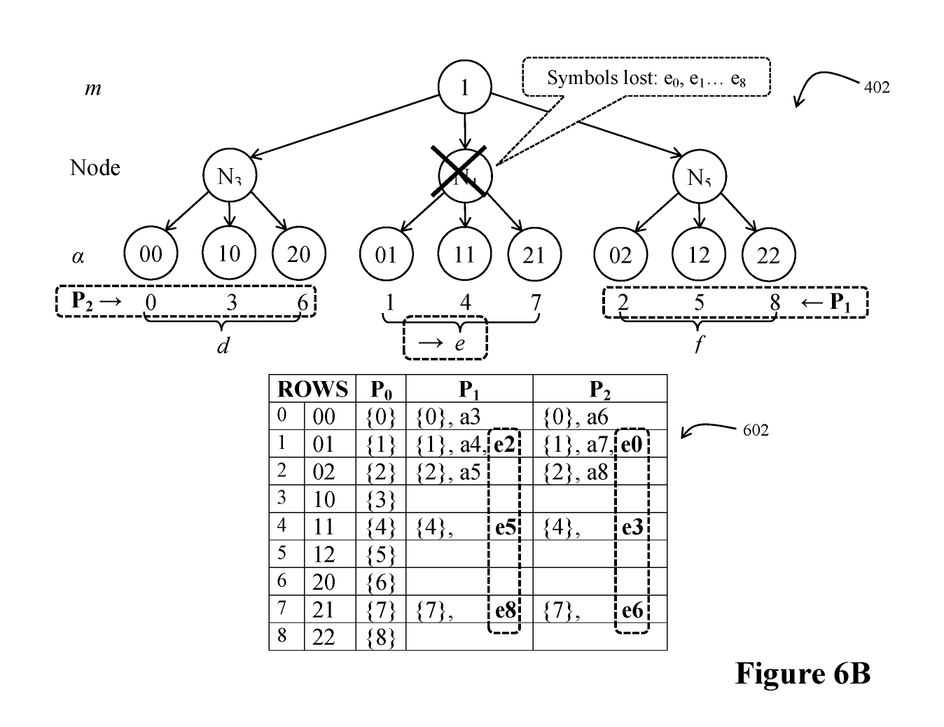

To this point the symbol array 702 has rather simply been populated with systematic symbols for each systematic node, row parity symbols for the first parity node and row parity symbols for the remaining parity nodes. However, the remaining m symbols must now be determined for each row of the parity nodes for all but the first parity node P₀ before the symbols pₛₜ for t={1, 2, . . . r−1} are complete. These additional m symbols are determined using the m r-Ary tree structure discussed with reference to FIG. 4 and by following the steps of the method 320 shown in FIG. 5. The additional m symbols, together with the row parity symbols, will be suitable to form a consistent set of linear equations to solve for systematic data recovery operations. In particular, for any loss of a systematic node Nⱼ, the β parity symbols from each parity node Pₜ (t=0, 1, . . . , r−1) will contribute r*β=α linear equations involving a unknowns. This will enable the storage system (e.g., a host device) to form the set of linear equations needed to solve for a unknowns and thus recover all systematic symbols of the lost systematic node Nⱼ. Again, the design of the m r-Ary trees will show that with the loss of any systematic node (1^{st} level node), its systematic symbols can be recovered by accessing the β parity symbols from the rows given by its leaf-nodes from each of the parity nodes. FIG. 5 will be further explained with reference to FIGS. 6A-B and FIG. 7.

FIG. 5 shows the steps involved in an exemplary method 320 for completing the parity symbols pₛₜ for t={1, 2, . . . , r−1}. The process begins at start step 501 and advances to step 502, where counters for the root node index i and the 1^{st} level (systematic) node index j are set to 0 and the parity node index t is set to 1. Next at step 504, a determination is made as to whether the systematic node index j is less than k. In other words, this step involves checking whether the currently selected systematic node Nⱼ is in fact a member of the k systematic nodes represented in the m r-Ary trees (see FIG. 4). If j<k, the method proceeds to step 506, where the leaf node indices for the node Nⱼ sub-tree are identified. Again, the leaf node indices are expressed as base-r m-digit numbers. With reference to the example of FIG. 6A, this means that the leaf node indices 00, 01 and 02 for the node N₀ are identified at step 506 in the first iteration through the method 320.

Next at step 508, symbols are determined and added to the symbol array for the parity node Pₜ (which is P₁ in the first iteration). The symbols are added to the rows in the symbol array having the same indices as the leaf node indices identified in step 506. Each symbol is expressed as the letter designating the node Nⱼ sub-tree and the decimal forms of the leaf node indices of a different sub-tree under the root node with index i. In some embodiments, the different sub-tree may be selected in a left to right manner, with the sub-tree to the immediate right of the node Nⱼ sub-tree being the first chosen and returning to the first sub-tree under root node i after reaching the last sub-tree under root node i. In other embodiments, the different sub-tree may be any other sub-tree under root node i (i.e., selecting the different sub-tree in a left to right order is optional). With reference to the example of FIG. 6A and the corresponding partial symbol array 602, it can be seen that step 508 results in one symbol being added to each of rows 00, 01 and 02 in the column for parity node P₁. These symbols are a₃, a₄ and a₅ and each consists of the letter a that designates the N₀ subtree and the decimal form of one of the leaf node indices from the next systematic node N₁ under the root node with index i=0. As should be apparent, in some embodiments, the leaf node indices to be used in the symbols may be chosen in left to right succession, but other orderings are also valid.

After adding the symbols in step 508, the method moves to step 510 where it is determined whether there is another different sub-tree under the root node with the index i (which for the first iteration remains set at 0). If so, the parity node index t is incremented by 1 (i.e., t=t+1) at step 512 and the method then returns to step 508 where symbols are determined and added to the symbol array for the parity node P₁ (which is now P₂ in this iteration). Again, the symbols are added to the rows in the symbol array having the same indices as the leaf node indices identified in step 506. The symbols are expressed as the letter designating the node Nⱼ sub-tree and the decimal forms of the leaf node indices of a different sub-tree under the root node with index i. Following the example of FIG. 6A, and with reference to the corresponding partial symbol array 602, it can be seen that the second iteration of step 508 results in one symbol being added to each of rows 00, 01 and 02 in the column for parity node P₂. These symbols are a₆, a₇ and a₈.

When it is determined at step 510 that there are no other different sub-trees under the root node with index i, the method advances to step 514 where the parity node index t is again set to 1 and the systematic node index j is incremented by 1. Next, a determination is made at step 516 as to whether the systematic node Nⱼ is under the root node with index i. As can be seen from FIG. 4, incrementing j in the current example results in the selection of systematic node N₁ and this systematic node is in fact under the root node with index i=0 per the determination of step 516. After determining that the new systematic node Nⱼ is under the root node with index i, the exemplary method returns to step 504 and is repeated from there as described above. In the next iteration through the method steps from 504 to 516, additional symbols are added to the symbol array for the HMSR erasure code. As can be seen from the m r-Ary tree structure of FIG. 4 and the completed symbol array 702 of FIG. 7, this next iteration results in symbols b₆, b₇ and b₈ being added to rows 10, 11, and 12 in the P₁ parity node column and the symbols b₀, b₁ and b₂ being added to rows 10, 11, and 12 in the P₂ parity node column. One more iteration of steps 504 to 516 will result in symbols c₀, c₁ and c₂ being added to rows 20, 21, and 22 in the P₁ parity node column and the symbols c₃, c₄ and c₅ being added to rows 20, 21, and 22 in the P₂ parity node column.

When it is finally determined at step 516 that node N (after incrementing j by 1 at step 514) is not under the root node with index i, the method moves to step 518 where the root node index i is incremented by 1 before again returning to step 504 for more iterations. Thus, as can be seen from the example of FIG. 4, after incrementing from systematic N₂ to systematic N₃ at step 514, it will be determined at step 516 that systematic N₃ does not fall under root node with index i=0 and i will be incremented to 1 at step 518. Continuing to iterate through steps 504 to 518 will result in the completion of the parity symbols pₛₜ for t={1, 2, . . . r−1}.

As shown in the completed symbol array 702 of FIG. 7, the first iteration after incrementing to i=1 will result in the symbols d₁, d₄ and d₇ being added to rows 00, 10, and 20 in the P₁ parity node column and the symbols d₂, d₅ and d₈ being added to rows 00, 10, and 20 in the P₂ parity node column. A second iteration for the case of i=1 will result in the symbols e₂, e₅ and e₈ being added to rows 01, 11, and 21 in the P₁ parity node column and the symbols e₀, e₃ and e₆ being added to rows 01, 11, and 21 in the P₂ parity node column. This second iteration is illustrated in FIG. 6B for greater clarity. And lastly, a third iteration for the case of i=1 will result in the symbols f₀, f₃ and f₆ being added to rows 02, 12, and 22 in the P₁ parity node column and the symbols f₁, f₄ and f₇ being added to rows 02, 12, and 22 in the P₂ parity node column.

During the iterations of steps 504 to 518, when it is finally determined at step 504 that j<k is not true, the method will end at step 520. For instance, at the end of the third iteration for the case of i=1 in the example of a HMSR (9, 6) erasure code, the systematic node index j will be incremented to 6 at step 516 and root node index i will be incremented to 2 at step 518. Then, upon returning to step 504 it will be determined that j<k is not true, which will cause the method to end at step 520.

Completion of method 300 (FIG. 3) through step 320 (as detailed in FIG. 5), will result in completion of a symbol array 702 for the desired HMSR erasure code, as shown in FIG. 7. Then at step 322 (FIG. 3), a codeword array can be generated from the symbol array by forming linear combinations of the symbols in each cell of the symbol array. In generating the codeword array, random number coefficients or other coefficients may be added to the linear combinations formed for the parity nodes P, for t={1, 2, . . . r−1}. Doing so will result in a HMSR erasure code that will have practical application in storage systems. For the example of the HMSR (9, 6) erasure code, FIG. 7 shows an exemplary codeword array 704 (symbols for systematic nodes N₀−N₅ are omitted for brevity) generated from the symbol array 702 that was produced as described above. As can be seen, coefficients may in some embodiments be added to all but the first k systematic symbols {aₛ, b₅, cₛ, . . . } from each s^{th} row and the additional m systematic symbols added to that row. Coefficients may not be needed for the first k systematic symbols from each s^{th} row because in any linear combination the first coefficient can be assumed to be 1, without any loss of generality. Similarly, because the last m symbols are newly added in every parity symbols (other than P₀), in some examples, their coefficients can also be assumed to be 1. However, in any cases where either of these assumptions violates linear independence of the set of equations for recovery, then coefficients may be added for these symbols like all other symbols. In some embodiments, the random number coefficients may be any integers between 000 and 255, which will make for efficient processing by some common microprocessors. For example, such a range of random numbers can allow for more efficient processing and solving of linear equations by an Intel Storage Acceleration Library (ISA-L), as provided by Intel Corporation. The use of such random number coefficients has been found to work successfully for (6, 4), (9, 6), (10, 8), (12, 9), (12, 8) erasures code which are frequently used erasures codes in distributed storage systems. During testing, no recovery failure was observed with the assignment of such coefficients for such erasure codes. Thus ensuring the linear independence of the set of linear equations generated for each single failure cases. In the case of violation of linear independence for certain erasure codes, a new set of random number or other coefficients can be generated to validate the recovery process of the k systematic nodes. After generation of the codeword array at step 322, the exemplary method 300 of FIG. 3 ends at step 324.

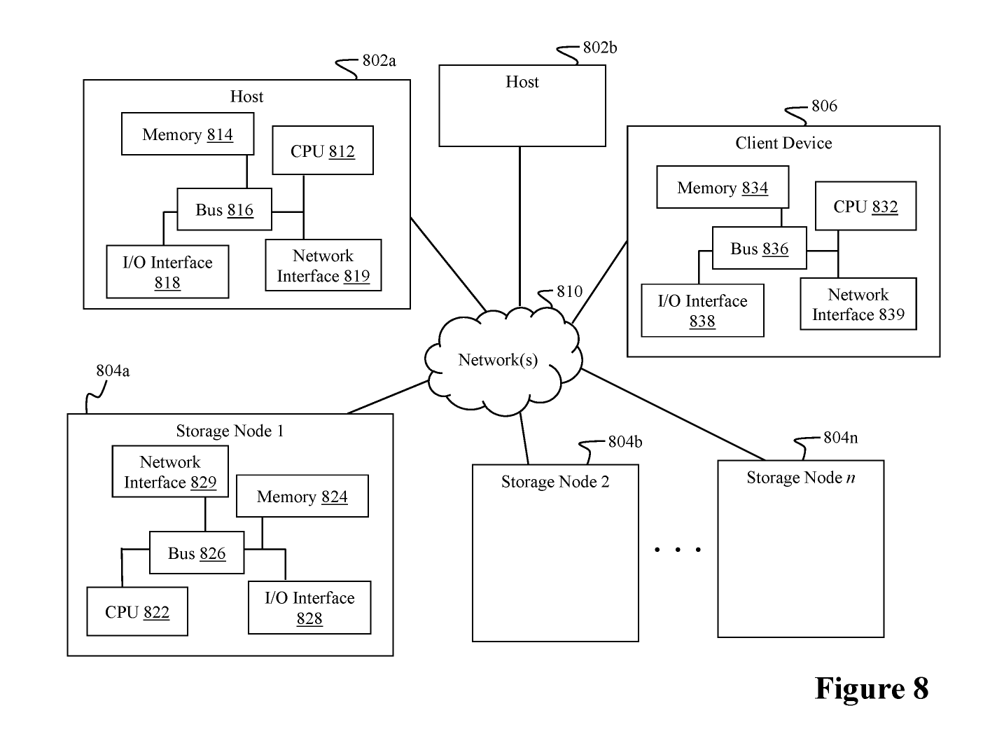

FIG. 8 is a block diagram illustrating an exemplary environment in which certain embodiments may be implemented. The environment may include one or more host 802a, 804b, a plurality of storage nodes 804a, 804b . . . 804n, and one or more client devices 806. The host devices 802a, 804b, storage nodes 804a, 804b . . . 804n, and client device(s) 806 may be interconnected by one or more networks 810. The network(s) 810 may be or include, for example, one or more of a local area network (LAN), a wide area network (WAN), a storage area network (SAN), the Internet, or any other type of communication link or combination of links. In addition, the network(s) 810 may include system busses or other fast interconnects.

The exemplary system shown in FIG. 8 may be any one of an application server farm, a storage server farm (or storage area network), a web server farm, a switch or router farm, or any other type of storage network. Although two hosts 802a, 802b, n storage nodes 804a, 804b . . . 804n, and one client 806 are shown, it is to be understood that the environment may include more or less of each type of device, as well as other commonly deployed network devices and components, depending on the particular application and embodiment(s) to be implemented. The hosts 802a, 802b may be, for example, computers such as application servers, storage servers, web servers, etc. Alternatively or additionally, hosts 802a, 802b could be or include communication modules, such as switches, routers, etc., and/or other types of machines. Although each of the hosts 802a, 802b are represented as single devices, a particular host 802a, 802b may be a distributed machine, which has multiple nodes that form a distributed and parallel processing system.

Each host 802a, 802b may include one or more CPU 812, such as a microprocessor, microcontroller, application-specific integrated circuit (“ASIC”), state machine, or other processing device etc. The CPU 812 executes computer-executable program code comprising computer-executable instructions for causing the CPU 812, and thus the host 802a, 802b, to perform certain methods and operations. For example, the computer-executable program code can include computer-executable instructions for causing the CPU to execute a storage operating system and at least some of the methods described herein for constructing HMSR erasure codes and for encoding, storing and retrieving and decoding data chunks in the various storage nodes 804a, 804b, . . . 804n. The CPU 812 may be communicatively coupled to a memory 814 via a bus 816 for accessing program code and data stored in the memory 814.

The memory 814 can comprise any suitable non-transitory computer readable media that stores executable program code and data. For example, the computer-readable medium can include any electronic, optical, magnetic, or other storage device capable of providing a processor with computer-readable instructions or other program code. Non-limiting examples of a computer-readable medium include a floppy disk, CD-ROM, DVD, magnetic disk, memory chip, ROM, RAM, an ASIC, a configured processor, optical storage, magnetic tape or other magnetic storage, or any other medium from which a computer processor can read instructions. The program code or instructions may include processor-specific instructions generated by a compiler and/or an interpreter from code written in any suitable computer-programming language, including, for example, C, C++, C#, Visual Basic, Java, Python, Perl, JavaScript, and ActionScript. Although not shown as such, the memory 814 could also be external to a particular host 802a, 802b, e.g., in a separate device or component that is accessed through a dedicated communication link and/or via the network(s) 810. A host 802b, 802b may also comprise any number of external or internal devices, such as input or output devices. For example, host 802a is shown with an input/output (“I/O”) interface 818 that can receive input from input devices and/or provide output to output devices.

A host 802a, 802b can also include at least one network interface 819. The network interface 819 can include any device or group of devices suitable for establishing a wired or wireless data connection to one or more of the networks 810 or directly to a network interface 829 of a storage node 804a, 804b, . . . 804n and/or a network interface 839 of a client device 806. Non-limiting examples of a network interface 819, 829, 839 can include an Ethernet network adapter, a modem, and/or the like to establish a TCP/IP connection with a storage node 804a, 804b, . . . 804n or a SCSI interface, USB interface, or a fiber wire interface to establish a direct connection with a storage node 804a, 804b, . . . 804n.

Each storage node 804a, 804b, . . . 804n may include similar components to those shown and described for the hosts 802a, 802b. For example, storage nodes 804a, 804b, . . . 804n may include a CPU 822, memory 824, a network interface 829, and an I/O interface 828 all communicatively coupled via a bus 826. The components in storage node 804a, 804b, . . . 804n function in a similar manner to the components described with respect to the hosts 802a, 802b. By way of example, the CPU 822 of a storage node 804a, 804b, . . . 804n may execute computer-executable instructions for storing, retrieving and processing data in memory 824, which may include multiple tiers of internal and/or external memories.

Each of the hosts 802a, 802b can be coupled to one or more storage node(s) 804a, 804b, . . . 804n. Each of the storage nodes 804a, 804b, . . . 804n could be an independent memory bank. Alternatively, storage nodes 804a, 804b, . . . 804n could be interconnected, thus forming a large memory bank or a subcomplex of a large memory bank. Storage nodes 804a, 804b, . . . 804n may be, for example, storage disks, magnetic memory devices, optical memory devices, flash memory devices, combinations thereof, etc., depending on the particular implementation and embodiment. In some embodiments, each storage node 804a, 804b, . . . 804n may include multiple storage disks, magnetic memory devices, optical memory devices, flash memory devices, etc. Each of the storage nodes 804a, 804b, . . . 804n can be configured, e.g., by a host 802a, 802b or otherwise, to serve as a systematic node or a parity node in accordance with the various embodiments described herein.

A client device 806 may also include similar components to those shown and described for the hosts 802a, 802b. For example, a client device 806 may include a CPU 832, memory 834, a network interface 829, and an I/O interface 838 all communicatively coupled via a bus 836. The components in a client device 806 function in a similar manner to the components described with respect to the hosts 802a, 802b. By way of example, the CPU of a client device 806 may execute computer-executable instructions for allowing a storage network architect, administrator or other user to design the m r-Ary tree structures, symbol arrays and/or codeword arrays for HMSR erasure codes, as described herein. Such computer-executable instructions and other instructions and data may be stored in the memory 834 of the client device 806 or in any other internal or external memory accessible by the client device. In some embodiments, the user of the client device may interact with the program(s) executing on the client device 806, for example with input and output devices, to design and construct desired tree structures, symbol arrays and codeword arrays. In other embodiments, the execution of the program code may cause the desired tree structures, symbol arrays and codeword arrays to be designed and constructed in an automated fashion. As noted, host(s) may alternatively or additional execute such program(s) for designing and constructing tree structures, symbol arrays and codeword arrays for HMSR erasure codes according to the methods described herein.

It will be appreciated that the depicted hosts 802a, 802b, storage nodes 804a, 804b, . . . 804n and client device 806 are represented and described in relatively simplistic fashion and are given by way of example only. Those skilled in the art will appreciate that actual hosts, storage nodes, client devices and other devices and components of a storage network may be much more sophisticated in many practical applications and embodiments. In addition, the hosts 802a, 802b and storage nodes 804a, 804b, . . . 804n may be part of an on-premises system and/or may reside in cloud-based systems accessible via the networks 810.

### GENERAL CONSIDERATIONS

Numerous specific details are set forth herein to provide a thorough understanding of the claimed subject matter. However, those skilled in the art will understand that the claimed subject matter may be practiced without these specific details. In other instances, methods, apparatuses, or systems that would be known by one of ordinary skill have not been described in detail so as not to obscure claimed subject matter.

Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

Some embodiments described herein may be conveniently implemented using a conventional general purpose or a specialized digital computer or microprocessor programmed according to the teachings herein, as will be apparent to those skilled in the computer art. Some embodiments may be implemented by a general purpose computer programmed to perform method or process steps described herein. Such programming may produce a new machine or special purpose computer for performing particular method or process steps and functions (described herein) pursuant to instructions from program software. Appropriate software coding may be prepared by programmers based on the teachings herein, as will be apparent to those skilled in the software art. Some embodiments may also be implemented by the preparation of application-specific integrated circuits or by interconnecting an appropriate network of conventional component circuits, as will be readily apparent to those skilled in the art. Those of skill in the art will understand that information may be represented using any of a variety of different technologies and techniques.

Some embodiments include a computer program product comprising a computer readable medium (media) having instructions stored thereon/in that, when executed (e.g., by a processor), cause the executing device to perform the methods, techniques, or embodiments described herein, the computer readable medium comprising instructions for performing various steps of the methods, techniques, or embodiments described herein. The computer readable medium may comprise a non-transitory computer readable medium. The computer readable medium may comprise a storage medium having instructions stored thereon/in which may be used to control, or cause, a computer to perform any of the processes of an embodiment. The storage medium may include, without limitation, any type of disk including floppy disks, mini disks (MDs), optical disks, DVDs, CD-ROMs, micro-drives, and magneto-optical disks, ROMs, RAMs, EPROMs, EEPROMs, DRAMs, VRAMs, flash memory devices (including flash cards), magnetic or optical cards, nanosystems (including molecular memory ICs), RAID devices, remote data storage/archive/warehousing, or any other type of media or device suitable for storing instructions and/or data thereon/in.

Stored on any one of the computer readable medium (media), some embodiments include software instructions for controlling both the hardware of the general purpose or specialized computer or microprocessor, and for enabling the computer or microprocessor to interact with a human user and/or other mechanism using the results of an embodiment. Such software may include without limitation device drivers, operating systems, and user applications. Ultimately, such computer readable media further includes software instructions for performing embodiments described herein. Included in the programming (software) of the general-purpose/specialized computer or microprocessor are software modules for implementing some embodiments.

The various illustrative logical blocks, modules, and circuits described in connection with the embodiments disclosed herein may be implemented or performed with a general-purpose processing device, a digital signal processor (DSP), an application-specific integrated circuit (ASIC), a field programmable gate array (FPGA) or other programmable logic device, discrete gate or transistor logic, discrete hardware components, or any combination thereof designed to perform the functions described herein. A general-purpose processing device may be a microprocessor, but in the alternative, the processor may be any conventional processor, controller, microcontroller, or state machine. A processing device may also be implemented as a combination of computing devices, e.g., a combination of a DSP and a microprocessor, a plurality of microprocessors, one or more microprocessors in conjunction with a DSP core, or any other such configuration

Aspects of the methods disclosed herein may be performed in the operation of such processing devices. The order of the blocks presented in the figures described above can be varied—for example, some of the blocks can be re-ordered, combined, and/or broken into sub-blocks. Certain blocks or processes can be performed in parallel.

The use of “adapted to” or “configured to” herein is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Headings, lists, and numbering included herein are for ease of explanation and are not meant to be limiting.

While the present subject matter has been described in detail with respect to specific examples thereof, it will be appreciated that those skilled in the art, upon attaining an understanding of the foregoing may readily produce alterations to, variations of, and equivalents to such aspects and examples. Accordingly, it should be understood that the present disclosure has been presented for purposes of example rather than limitation, and does not preclude inclusion of such modifications, variations, and/or additions to the present subject matter as would be readily apparent to one of ordinary skill in the art.

What is claimed is:

1. A method for generating a codeword array for a high-rate MSR (n, k) erasure code for a data storage system, wherein k represents a number of systematic nodes storing systematic data, n represents a total number of systematic nodes plus r parity nodes, and k is an integer multiple m of n greater than or equal to 2, the method comprising:
generating m r-Ary trees to represent the k systematic nodes and the r parity nodes;
generating a codeword array comprising a rows and n columns, wherein α represents the sub-packetization level of the codeword array;
populating the codeword array with appropriate systematic symbols in each of the α rows for each of the columns representing the k systematic nodes;
populating the codeword array with respective linear combinations of symbols in each of the α rows for the columns representing each of the r parity nodes;
determining from the m r-Ary trees an additional m symbols to be added to the linear combinations of symbols in each of the α rows for the columns representing each of the r parity nodes except the first parity node.

2. The method of claim 1, further comprising the step of adding coefficients to at least some of the symbols in each of the α rows for the columns representing each of the r parity nodes except the first parity node.

3. The method of claim 2, wherein each of the coefficients is a random number comprising an integer between 000 and 255.

4. The method of claim 1, wherein each of the m r-Ary trees has a root node and is given a root node index i, where i={0, . . . , m−1};
wherein each root node is parent to a plurality of first-level nodes representing a subset of the k systematic nodes and is given a first-level node index Nj, where j=r*i+t, 0≦t≦r−1;
wherein each of the k first-level nodes is parent to β leaf nodes representing a subset of the parity nodes, where β is equal to α/r;
wherein the β leaf nodes under the root node with a root node index i=0 are given leaf node indices comprising sequential base-r m-digit numbers;
wherein the leaf nodes under any remaining root nodes with root node indices i={1, . . . , m−1} are given leaf node indices determined by applying a right-shift-rotation operation the applicable i times to the corresponding leaf node indices of the leaf nodes under the root node with a root node index i=0; and
designating a decimal form for each of the respective leaf node indices and designating with a sequential letter {a, b, c, . . . } each subtree formed by one of the first-level nodes and its leaf nodes,
whereby the m r-Ary trees show that if any of the k systematic nodes fails, the systematic data previously stored on the failed systematic node can be recovered by accessing the symbols in the codeword array that are assigned to those of the β rows designated by the decimal form of each of the leaf nodes indices under the failed systematic node.

5. The method of claim 4, wherein determining from the m r-Ary trees the additional m symbols to be added to the linear combinations of symbols in each of the α rows for the columns representing each of the r parity nodes except the first parity node comprises:
(α) setting the root node index i=0 and the first-level node index j=0 and setting a parity node index t=1;
(b) identifying the leaf node indices for the sub-tree formed by the Nⱼ first-level node under the root node with root node index i;
(c) determining m symbols to be added to the linear combinations in the rows for the columns in the codeword array representing the parity node with parity node index t, wherein each of the m symbols is expressed as the letter designating the subtree formed by Nⱼ first-level node and the decimal forms of the leaf node indices of a different sub-tree under the root node with root node index i;
(d) adding each of the m symbols to the rows in the codeword array having the same indices as the leaf node indices identified in step (b);
(e) if there is another different sub-tree under the root node with root node index i, incrementing the parity node index t=t+1 and then repeating steps (c)-(e);
(f) if there is not another different sub-tree under the root node with root node index i, setting the parity node index t=0 and incrementing the first-level node index j=j+1;
(g) if the first-level node Nj is under the root node with root node index i, repeating steps (b)-(g); and
(h) if the first-level node Nj is not under the root node with root node index i, incrementing the root node index i=i+1 and then repeating steps (b)-(g).

6. The method of claim 4, wherein the high-rate MSR (n, k) erasure code is a (9, 6) erasure code, with m=2 and r=3;
wherein the m r-Ary trees comprise 2 ternary trees; and
wherein each of the leaf node indices of the ternary trees comprises a base-3 2-digit number.

7. The method of claim 1, wherein the high-rate MSR (n, k) erasure code is selected from the group consisting of: a (6, 4) erasure code, a (9, 6) erasure code, a (10, 8) erasure code, a (12, 8) erasure code, and a (12, 9) erasure code.

8. A non-transitory computer-readable medium having stored thereon instructions comprising machine executable code, which when executed by at least one computer, causes the computer to generate a codeword array for a high-rate MSR (n, k) erasure code for a data storage system, wherein k represents a number of systematic nodes storing systematic data, n represents a total number of systematic nodes plus r parity nodes, and k is an integer multiple m of n greater than or equal to 2, the method comprising:
generating m r-Ary trees to represent the k systematic nodes and the r parity nodes;
generating a codeword array comprising a rows and n columns, wherein α represents the sub-packetization level of the codeword array;
populating the codeword array with appropriate systematic symbols in each of the α rows for each of the columns representing the k systematic nodes;
populating the codeword array with respective linear combinations of symbols in each of the α rows for the columns representing each of the r parity nodes;
determining from the m r-Ary trees an additional m symbols to be added to the linear combinations of symbols in each of the α rows for the columns representing each of the r parity nodes except the first parity node.

9. The non-transitory computer-readable medium of claim 8, having stored thereon further instructions for causing the computer to coefficients to at least some of the symbols in each of the α rows for the columns representing each of the r parity nodes except the first parity node.

10. The non-transitory computer-readable medium of claim 9, wherein adding the coefficients will result in the a high-rate MSR erasure code having practical application in storage systems.

11. The non-transitory computer-readable medium of claim 8, wherein each of the m r-Ary trees has a root node and is given a root node index i, where i={0, . . . , m−1};
wherein each root node is parent to a plurality of first-level nodes representing a subset the k systematic nodes and is given a first-level node index Nj, where j=r*i+t, 0≦t≦r−1;
wherein each of the k first-level nodes is parent to β leaf nodes representing a subset of the parity nodes, where β is equal to α/r;
wherein the β leaf nodes under the root node with a root node index i=0 are given leaf node indices comprising sequential base-r m-digit numbers;
wherein the leaf nodes under any remaining root nodes with root node indices i={1, . . . , m−1} are given leaf node indices determined by applying a right-shift-rotation operation the applicable i times to the corresponding leaf node indices of the leaf nodes under the root node with a root node index i=0; and
a decimal form for each of the respective leaf node indices is denoted and a sequential letter {a, b, c, . . . } is used to designate each subtree formed by one of the first-level nodes and its leaf nodes,
whereby the m r-Ary trees show that if any of the k systematic nodes fails, the systematic data previously stored on the failed systematic node can be recovered by accessing the symbols in the codeword array that are assigned to those of the β rows designated by the decimal form of each of the leaf nodes indices under the failed systematic node.

12. The non-transitory computer-readable medium of claim 11, wherein determining from the m r-Ary trees the additional m symbols to be added to the linear combinations of symbols in each of the α rows for the columns representing each of the r parity nodes except the first parity node comprises:
(α) setting the root node index i=0 and the first-level node index j=0 and setting a parity node index t=1;
(b) identifying the leaf node indices for the sub-tree formed by the Nⱼ first-level node under the root node with root node index i;
(c) determining m symbols to be added to the linear combinations in the rows for the columns in the codeword array representing the parity node with parity node index t, wherein each of the m symbols is expressed as the letter designating the subtree formed by Nⱼ first-level node and the decimal forms of the leaf node indices of a different sub-tree under the root node with root node index i;
(d) adding each of the m symbols to the rows in the codeword array having the same indices as the leaf node indices identified in step (b);
(e) if there is another different sub-tree under the root node with root node index i, incrementing the parity node index t=t+1 and then repeating steps (c)-(e);
(f) if there is not another different sub-tree under the root node with root node index i, setting the parity node index t=0 and incrementing the first-level node index j=j+1;
(g) if the first-level node Nj is under the root node with root node index i, repeating steps (b)-(g); and
(h) if the first-level node Nj is not under the root node with root node index i, incrementing the root node index i=i+1 and then repeating steps (b)-(g).

13. The non-transitory computer-readable medium of claim 11, wherein the high-rate MSR (n, k) erasure code is a (9, 6) erasure code, with m=2 and r=3;
wherein the m r-Ary trees comprise 2 ternary trees; and
wherein each of the leaf node indices of the ternary trees comprises a base-3 2-digit number.

14. The non-transitory computer-readable medium of claim 8, wherein the high-rate MSR (n, k) erasure code is selected from the group consisting of: a (6, 4) erasure code, a (9, 6) erasure code, a (10, 8) erasure code, a (12, 8) erasure code, and a (12, 9) erasure code.

15. A storage system, comprising:
a processor device; and
a memory device including program code stored thereon, wherein the program code, upon execution by the processor device, performs operations for generating a codeword array for a high-rate MSR (n, k) erasure code for the storage system, wherein k represents a number of systematic nodes storing systematic data, n represents a total number of systematic nodes plus r parity nodes, and k is an integer multiple m of n greater than or equal to 2, the operations comprising:
generating m r-Ary trees to represent the k systematic nodes and the r parity nodes;
generating a codeword array comprising a rows and n columns, wherein α represents the sub-packetization level of the codeword array;
populating the codeword array with appropriate systematic symbols in each of the α rows for each of the columns representing the k systematic nodes;
populating the codeword array with respective linear combinations of symbols in each of the α rows for the columns representing each of the r parity nodes;
determining from the m r-Ary trees an additional m symbols to be added to the linear combinations of symbols in each of the α rows for the columns representing each of the r parity nodes except the first parity node.

16. The method of claim 15, further comprising the step of adding coefficients to at least some of the symbols in each of the α rows for the columns representing each of the r parity nodes except the first parity node.

17. The method of claim 16, wherein adding the coefficients will result in the a high-rate MSR erasure code having practical application in storage systems.

18. The method of claim 15, wherein each of them r-Ary trees has a root node and is given a root node index i, where i={0, . . . , m−1};
wherein each root node is parent to a plurality of first-level nodes representing a subset of the k systematic nodes and is given a first-level node index Nj, where j=r*i+t, 0≦t≦r−1;
wherein each of the k first-level nodes is parent to β leaf nodes representing a subset of the parity nodes, where β is equal to α/r;
wherein the β leaf nodes under the root node with a root node index i=0 are given leaf node indices comprising sequential base-r m-digit numbers;
wherein the leaf nodes under any remaining root nodes with root node indices i={1, . . . , m−1} are given leaf node indices determined by applying a right-shift-rotation operation the applicable i times to the corresponding leaf node indices of the leaf nodes under the root node with a root node index i=0; and
designating a decimal form for each of the respective leaf node indices and designating with a sequential letter {a, b, c, . . . } each subtree formed by one of the first-level nodes and its leaf nodes,
whereby the m r-Ary trees show that if any of the k systematic nodes fails, the systematic data previously stored on the failed systematic node can be recovered by accessing the symbols in the codeword array that are assigned to those of the β rows designated by the decimal form of each of the leaf nodes indices under the failed systematic node.

19. The method of claim 18, wherein determining from the m r-Ary trees the additional m symbols to be added to the linear combinations of symbols in each of the α rows for the columns representing each of the r parity nodes except the first parity node comprises:
(α) setting the root node index i=0 and the first-level node index j=0 and setting a parity node index t=1;
(b) identifying the leaf node indices for the sub-tree formed by the Nⱼ first-level node under the root node with root node index i;
(c) determining m symbols to be added to the linear combinations in the rows for the columns in the codeword array representing the parity node with parity node index t, wherein each of the m symbols is expressed as the letter designating the subtree formed by Nⱼ first-level node and the decimal forms of the leaf node indices of a different sub-tree under the root node with root node index i;
(d) adding each of the m symbols to the rows in the codeword array having the same indices as the leaf node indices identified in step (b);
(e) if there is another different sub-tree under the root node with root node index i, incrementing the parity node index t=t+1 and then repeating steps (c)-(e);
(f) if there is not another different sub-tree under the root node with root node index i, setting the parity node index t=0 and incrementing the first-level node index j=j+1;
(g) if the first-level node Nj is under the root node with root node index i, repeating steps (b)-(g); and
(h) if the first-level node Nj is not under the root node with root node index i, incrementing the root node index i=i+1 and then repeating steps (b)-(g).

20. The method of claim 15, wherein the high-rate MSR (n, k) erasure code is selected from the group consisting of: a (6, 4) erasure code, a (9, 6) erasure code, a (10, 8) erasure code, a (12, 8) erasure code, and a (12, 9) erasure code.
